(19) United States
(12) Patent Application Publication
(10) Pub. No.: US 2002/0063251 A1
(43) Pub. Date: May 30, 2002

(54) Semiconductor device and testing method therefor

(76) Inventors: Sadashige Sugiura, Shiga (JP); Toshiyuki Yokoyama, Kyoto (JP)

Correspondence Address: MCDERMOTT WILL & EMERY, 600 13TH STREET, N.W., WASHINGTON, DC, 20005-3096, US

(21) Appl. No.: 09/994,936

(22) Filed: Nov. 28, 2001

(30) Foreign Application Priority Data
Nov. 28, 2000 (JP) 2000-360526

(51) Int. Cl. H01L 23/58

(52) U.S. Cl. 257/48

(57) ABSTRACT

A plurality of IPs can be mounted as chip IPs on a silicon wiring substrate. The silicon wiring substrate includes a plurality of wires. The IPs (chip IPs) are attached to and mounted on pads that are connected to the wires of the silicon wiring substrate. Test pads are provided on the silicon wiring substrate so as to be connected to wires that are connected to a power supply line, a ground line and an internal circuit in each IP. The condition of the connection between the IPs and the silicon wiring substrate is determined based on the fact that a forward current flows through a protection diode when a voltage of the opposite polarity is applied to the power supply line or the ground line. A test circuit for testing an electrical connection may be provided in each chip IP.

### BACKGROUND OF THE INVENTION

The present invention relates to a semiconductor device including various chip IPs mounted on a semiconductor wiring substrate provided with a wiring layer, a testing method therefor, and a function setting method therefor.

In recent years, a concept of system LSI has been proposed in the art, in which a plurality of LSIs are formed on a common substrate, and various methods for designing system LSIs have been proposed in the art. Particularly, system LSIs are advantageous in that various semiconductor device elements having various functions can be integrated together with a high degree of integration by accommodating a memory such as a DRAM, a logic LSI, an analog circuit such as a high frequency circuit, etc., in a single semiconductor device.

However, such conventional system LSIs have been confronted with the following problems in actually forming the devices.

The first problem is the difficulty in reducing the device manufacturing cost. This is due to the very high research and development cost for system LSIs and the difficulty in improving the production yield.

The second problem is the substantial wiring delay. Generally, the height of a device decreases according to a shrink rule. Then, as the cross-sectional area of the wiring decreases, the wiring delay, which is defined by RC (where R denotes the resistance, and C denotes the parasitic capacitance) increases. Thus, as far as the wiring delay is concerned, the disadvantage of miniaturization exceeds the advantage thereof. One way to solve the problem is to provide a buffer in the wiring. However, providing a buffer leads to another disadvantage of increasing the area and the power consumption of the device.

The third problem is the difficulty in reducing the noise. As the power supply voltage decreases, the current increases. Then, it will be difficult to suppress the increase in noise according to the increase in current. This is because the increase in noise due to miniaturization is unavoidable as the SN ratio deteriorates in proportion to the shrink ratio to the 3rd to 6th power. Therefore, it is important to suppress the power supply impedance.

One way to realize a semiconductor device incorporating various device elements of various functions while ensuring a large cross-sectional area of the wiring is to provide chip IPs including various device elements integrated therein to be mounted on a semiconductor wiring substrate having a wiring layer, e.g., a silicon wiring substrate. In such a case, a large number of chip IPs (IPs) are mounted on the wiring substrate, whereby it is more important to ensure reliable connection between the chip IPs and the wiring substrate, as compared to a conventional system LSI.

### SUMMARY OF THE INVENTION

An object of the present invention is to provide a semiconductor device and a testing method therefor, in which chip IPs, which can be design assets in the form of IPs, are mounted on a common semiconductor wiring substrate, while ensuring a reliable connection between the semiconductor wiring substrate and the chip IPs.

As a basic structure, a semiconductor device of the present invention includes: a semiconductor wiring substrate including a plurality of wires; a chip IP including a circuit having semiconductor device elements arranged therein, the chip IP being attached to and mounted on the semiconductor wiring substrate so that the circuit is electrically connected to the plurality of wires of the semiconductor wiring substrate; and at least one test pad connected to at least one of the wires of the semiconductor wiring substrate for testing an electrical connection between the circuit of the chip IP and the wires.

In this way, it is possible to easily and quickly test the electrical connection between each chip IP and the wires of the semiconductor wiring substrate by using the test pads provided on the semiconductor wiring substrate. Therefore, it is possible to suppress the decrease in the reliability of the electrical connection between each chip IP and the wires in the attachment process.

The test pad may be an external terminal pad of the semiconductor device, or a portion of the at least one of the wires that is exposed on a surface of the semiconductor wiring substrate.

The circuit of the chip IP may include a power supply line for supplying a power supply voltage and a node forming a protection diode between the power supply line and the node; and the test pad may include a first test pad connected to a wire that is connected to the power supply line and a second test pad connected to a wire that is connected to the node in the circuit. In this way, it is possible to easily detect the electrical connection by using a forward current through the protection diode.

The circuit of the chip IP may include a ground line for supplying a ground voltage and a node forming a protection diode between the ground line and the node; and the test pad may include a first test pad connected to a wire that is connected to the ground line and a second test pad connected to a wire that is connected to the node in the circuit. In this way, it is possible to easily detect the electrical connection by using a forward current through the protection diode.

The circuit of the chip IP may include a ground line for supplying a ground voltage, a power supply line for supplying a power supply voltage, and a selector for receiving, and selectively outputting one of, a signal of the ground line or the power supply line and an output signal of an output section of the circuit; and the test pad may include a first test pad connected to a wire for supplying a switching control signal for the selector and a second test pad connected to an output section of the selector. Also in this way, it is possible to easily detect the electrical connection.

A switching element for turning ON/OFF transmission of a signal from the test pad may be provided at a position that is along each of the plurality of wires of the semiconductor wiring substrate connected to the test pad and opposite to the chip IP with respect to the test pad. In this way, it is possible to prevent an excessive load from acting upon a circuit in another chip IP that is connected to the chip IP to be tested.

The semiconductor device may further include: a test circuit provided in the chip IP for testing an electrical connection between the circuit of the chip IP and the wires; and a setting circuit for setting at least the test circuit in a test mode, wherein the test pad may include a first test pad for supplying a test mode signal to the test circuit and the setting circuit and a second test pad for receiving an output of the test circuit. In this way, it is possible to more reliably test the electrical connection between each chip IP and the wires.

The test circuit may have a pull-down type circuit structure or a pull-up type circuit structure. In this way, it is possible to easily determine the condition of the electrical connection based on whether the monitor signal, which is used for the testing, is at an H-level or an L-level.

The setting circuit may be provided in the chip IP, or in a chip different from the chip IP.

Preferably, the circuit of the chip IP includes a power supply line for supplying a power supply voltage and a ground line for supplying a ground voltage; and the semiconductor device further includes: a third pad connected to a wire that is connected to the power supply line; and a fourth pad connected to a wire that is connected to the ground line.

A first method of the present invention is a method for testing a semiconductor device, the semiconductor device including: a semiconductor wiring substrate including a plurality of wires; and a chip IP including an internal circuit, the internal circuit including a power supply line for supplying a power supply voltage and a node forming a protection diode between the power supply line and the node, the chip IP being attached to and mounted on the semiconductor wiring substrate so that the internal circuit is electrically connected to the plurality of wires of the semiconductor wiring substrate, the method including, after forming a first test pad connected to one of the plurality of wires that is connected to the power supply line and a second test pad connected to another one of the plurality of wires that is connected to the node in the circuit, the steps of: (a) supplying a voltage lower than a voltage of the power supply line via the first test pad to the power supply line; and (b) detecting a voltage or a current at the node of the circuit via the second test pad, thereby testing an electrical connection between the circuit of the chip IP and the plurality of wires.

With this method, it is possible to easily and quickly test the electrical connection between the circuit of each chip IP and the wires of the semiconductor wiring substrate based on the fact that a portion functioning as a protection diode is provided in a semiconductor device element such as an MOS transistor that is typically connected directly to an input/output pad.

A second method of the present invention is a method for testing a semiconductor device, the semiconductor device including: a semiconductor wiring substrate including a plurality of wires; and a chip IP including an internal circuit, the internal circuit including a ground line for supplying a ground voltage and a node forming a protection diode between the ground line and the node, the chip IP being attached to and mounted on the semiconductor wiring substrate so that the internal circuit is electrically connected to the plurality of wires of the semiconductor wiring substrate, the method including, after forming a first test pad connected to one of the plurality of wires that is connected to the ground line and a second test pad connected to another one of the plurality of wires that is connected to the node in the circuit, the steps of: (a) supplying a voltage higher than a voltage of the ground line via the first test pad to the ground line; and (b) detecting a voltage or a current at the node of the circuit via the second test pad, thereby testing an electrical connection between the circuit of the chip IP and the plurality of wires.

With this method, it is possible to easily and quickly test the electrical connection between the circuit of each chip IP and the wires of the semiconductor wiring substrate based on the fact that a portion functioning as a protection diode is provided in a semiconductor device element such as an MOS transistor that is typically connected directly to an input/output pad.

A third method of the present invention is a method for testing a semiconductor device, the semiconductor device including: a semiconductor wiring substrate including a plurality of wires; and a chip IP including an internal circuit, the internal circuit including a power supply line for supplying a power supply voltage and a node forming a protection diode between the power supply line and the node, the chip IP being attached to and mounted on the semiconductor wiring substrate so that the internal circuit is electrically connected to the plurality of wires of the semiconductor wiring substrate, the method including, after forming a test circuit in the chip IP for testing an electrical connection between the circuit of the chip IP and the wires and a setting circuit for setting the circuit in the chip IP and the test circuit in a test mode, and after forming a first test pad connected to one of the plurality of wires that is connected to the setting circuit and a second test pad connected to another one of the plurality of wires that is connected to the test circuit, the steps of: (a) inputting a test mode setting signal via the first test pad to the setting circuit and the test circuit; and (b) detecting an output of the test circuit via the second test pad, thereby testing the electrical connection between the circuit of the chip IP and the plurality of wires.

With this method, it is possible to easily and quickly test the electrical connection between the circuit of each chip IP and the wires of the semiconductor wiring substrate in a more reliable manner by using the test circuit.

The test circuit may be formed to have a pull-down type circuit structure; in the step (a), the test mode setting signal may be input so that an H-level signal is output from the setting circuit; and in the step (b), the electrical connection between the chip IP and the plurality of wires may be determined to be good when the output from the test circuit is at an H level.

The test circuit may be formed to have a pull-up type circuit structure; in the step (a), the test mode setting signal may be input so that an L-level signal is output from the setting circuit; and in the step (b), the electrical connection between the chip IP and the plurality of wires may be determined to be good when the output from the test circuit is at an L level.

A plurality of the chip IPs may be provided; the circuit of each chip IP may include a power supply line for supplying a power supply voltage and a ground line for supplying a ground voltage; the semiconductor device may further include: a third pad connected to a wire that is connected to the power supply line; a fourth pad connected to a wire that is connected to the ground line; a switching device for turning ON/OFF an electric conduction of a wire between the chip IPs; and a selector for switching outputs from the respective chip IPs from one to another, wherein the switching device and the selector may be controlled by the setting circuit so that the steps (a) and (b) are performed successively for each of the chip IPs. In this way, it is possible to test the connection between each chip IP and the wiring layer via external terminal pads.

### BRIEF DESCRIPTION OF THE DRAWINGS

FIG. 1A is a plan view illustrating a silicon wiring substrate to be a wiring substrate on which a group of IPs are mounted.

FIG. 1B is a plan view illustrating an example of a group of IPs to be mounted on the silicon wiring substrate.

FIG. 1C is a cross-sectional view illustrating the silicon wiring substrate.

FIG. 2 is a plan view illustrating a general structure of an IPOS device of a first embodiment, and a partial enlarged view thereof.

FIG. 3A is a block circuit diagram illustrating a first testing method for testing the connection between an IP (chip IP) and wiring according to the first embodiment.

FIG. 3B is a block circuit diagram illustrating a second testing method for testing the connection between an IP (chip IP) and wiring according to the first embodiment.

FIG. 4 is an enlarged plan view illustrating a portion of an IPOS device of a second embodiment.

FIG. 5 is an enlarged plan view illustrating a portion of an IPOS device of a third embodiment.

FIG. 6 is an electric circuit diagram of an IP and a setting circuit, illustrating an example where a test circuit of the third embodiment is of a pull-down type.

FIG. 7 is a plan view illustrating a portion of an IPOS device of a fourth embodiment.

### DESCRIPTION OF THE PREFERRED EMBODIMENTS

Basic Structure of the Present Invention

In order to realize a semiconductor device incorporating various device elements of various functions while ensuring a large cross-sectional area of the wiring, the present invention employs a structure in which chip IPs including various device elements therein are mounted on a semiconductor wiring substrate having a wiring layer, e.g., a silicon wiring substrate (Super-Sub). The circuit (IC) provided in each chip IP can be treated as an IP (Intellectual Property) in the design of a semiconductor device, and the semiconductor device of the present invention can be considered as a product obtained by attaching various IPs on a semiconductor wiring substrate. Therefore, the semiconductor device as a whole is an “IP On Super-Sub”, and thus the semiconductor device as a whole including the silicon wiring substrate and the group of IPs will be referred to as an “IPOS device” in the present specification.

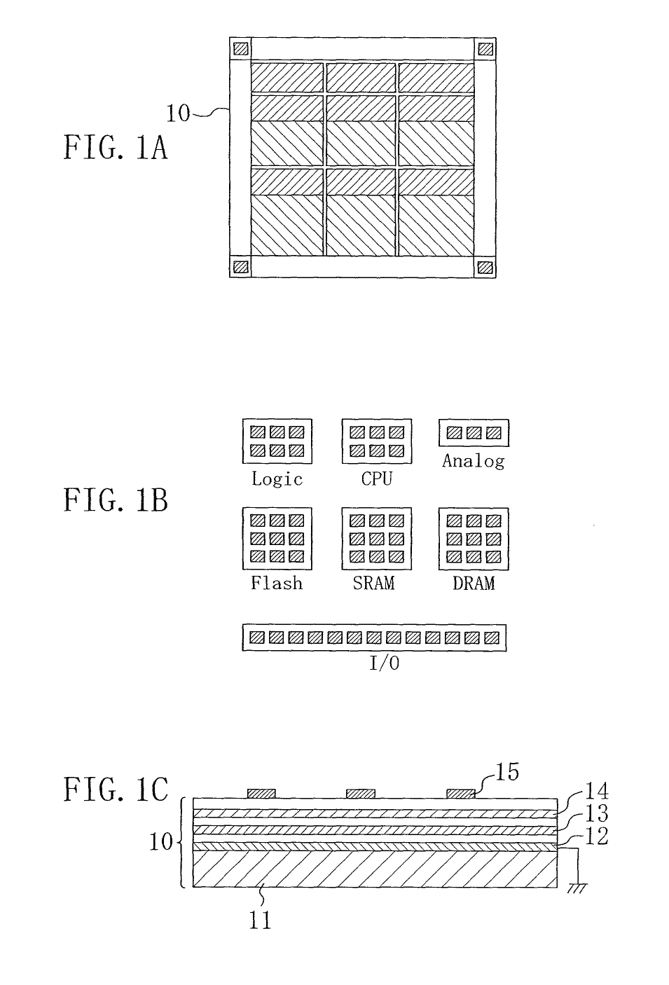

FIG. 1A, FIG. 1B and FIG. 1C are a plan view illustrating a silicon wiring substrate to be the wiring substrate for mounting a group of IPs (chip IPs), a plan view illustrating an example of the group of IPs to be mounted on the silicon wiring substrate, and a cross-sectional view illustrating the silicon wiring substrate, respectively. As illustrated in FIG. 1A and FIG. 1B, a plurality of regions for mounting various IPs are provided on a silicon wiring substrate 10. For example, a group of various IPs, such as Analog-IP, Logic-IP, CPU-IP, Flash Memory-IP, SRAM-IP, DRAM-IP and I/o-IP, can be mounted as chip IPs in the respective regions. As illustrated in FIG. 1C, the silicon wiring substrate 10 includes a silicon substrate 11, a ground plane 12 provided on the silicon substrate 11 via an insulative film (not shown), a first wiring layer 13 provided on the ground plane 12 via an interlayer insulative film, a second wiring layer 14 provided on the first wiring layer 13 via an interlayer insulative film, and pads 15 provided on the second wiring layer 14 via a passivation film. The pads 15, the wiring layers 13 and 14 and the ground plane 12 are connected to one another at desired positions via contacts (not shown). Each IP is attached on the pad 15 so that the IP is electrically connected to another IP or to the ground plane 12 via the wiring layers 13 and 14.

The dimensional limitation of the wiring layers 13 and 14 in the silicon wiring substrate 10 is not strict, and even a wire whose width is on the order of 1 μm can be provided, thereby providing the following effects. A dimension of wiring of the generation that had the best wiring characteristics among a number of generations through which semiconductor integrated circuit devices have been miniaturized can be selected empirically. The electrical impedance can also be reduced.

While a large number of chip IPs functioning as IPs are mounted on the silicon wiring substrate, there is needed means for efficiently determining the condition of the signal connection between the wiring layer of the silicon wiring substrate and the IPs and the condition of the electrical connection between the IPs. The embodiments of the present invention will now be described with respect to such a determination of the condition of connection.

First Embodiment

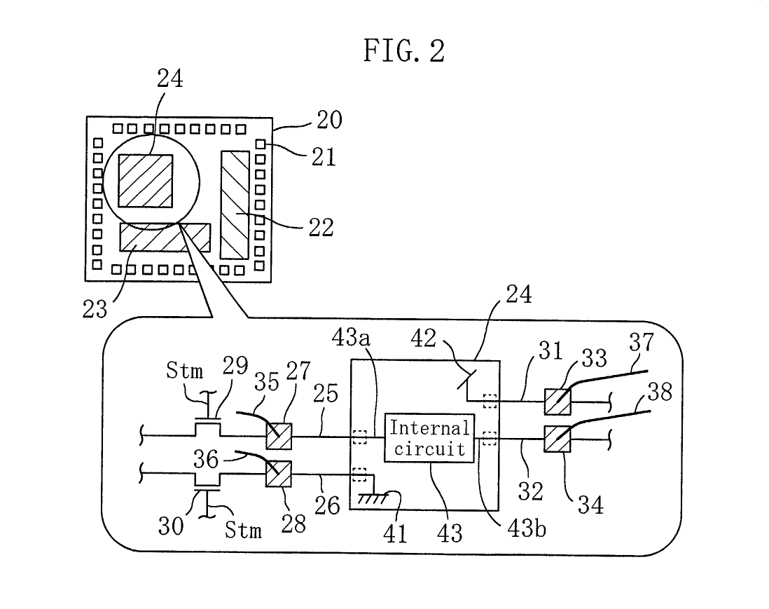

FIG. 2 is a plan view illustrating a general structure of an IPOS device of the present embodiment, and a partial enlarged view thereof. As illustrated in the figure, external terminal pads 21 for electrically connecting the circuits in the IPOS device to external devices are provided on the upper surface of a silicon wiring substrate 20 along the periphery thereof. IPs (chip IPs) 22, 23 and 24 incorporating various device elements therein are arranged on the silicon wiring substrate 20. Circuits in each IP are connected to the respective wires in the silicon wiring substrate via pads shown by broken lines in the figure (pads that are connected to the wiring on the silicon wiring substrate are shown overlapping with other pads that are connected to the circuits in the IP). As illustrated in the partial enlarged view of FIG. 2, wires 25, 26, 31 and 32 in the wiring layer of the silicon wiring substrate 20 are connected to the circuit of the IP 24 whose electrical connection is to be tested.

A feature of the present embodiment is the provision of test pads 27, 28, 33 and 34 connected respectively to the wires 25, 26, 31 and 32, which are connected to the circuit of the IP 24 whose electrical connection is to be tested. The wires 25, 26, 31 and 32 are provided in the form of the wiring layers 13 and 14 as illustrated in FIG. 1C, and the test pads 27, 28, 33 and 34 are connected respectively to the wires 25, 26, 31 and 32 via contacts. The wire 25 is connected to a node 43a of the circuit connected to an internal circuit 43 in the IP 24, and the wire 26 to a ground line 41 in the IP 24. The wire 31 is connected to a power supply line 42 in the IP 24, and the wire 32 to a node 43a of the internal circuit 43 in the IP 24.

Typically, the test pads 27, 28, 33 and 34 have generally the same structure as those denoted by reference numeral 15 in FIG. 1C. Alternatively, a wire of the wiring layer may be partially exposed on the surface so that the exposed portion can be used as a pad. The silicon wiring substrate 20, unlike a wiring layer provided on a chip IP, has a wide wire whose width is on the order of 10 μm, for example, and therefore a portion thereof as it is can be used as a test pad.

Switching transistors 29 and 30 are provided between the test pads 27 and 28 and another IP (chip IP) not shown in the figure. The switching transistors 29 and 30 are turned OFF upon receiving a test mode signal Stm. While the switching transistors 29 and 30 are provided in advance in the silicon wiring substrate 20, they may alternatively be provided in the respective IPs. Moreover, the switching transistors 29 and 30 may not be provided particularly when there is no IP to be protected.

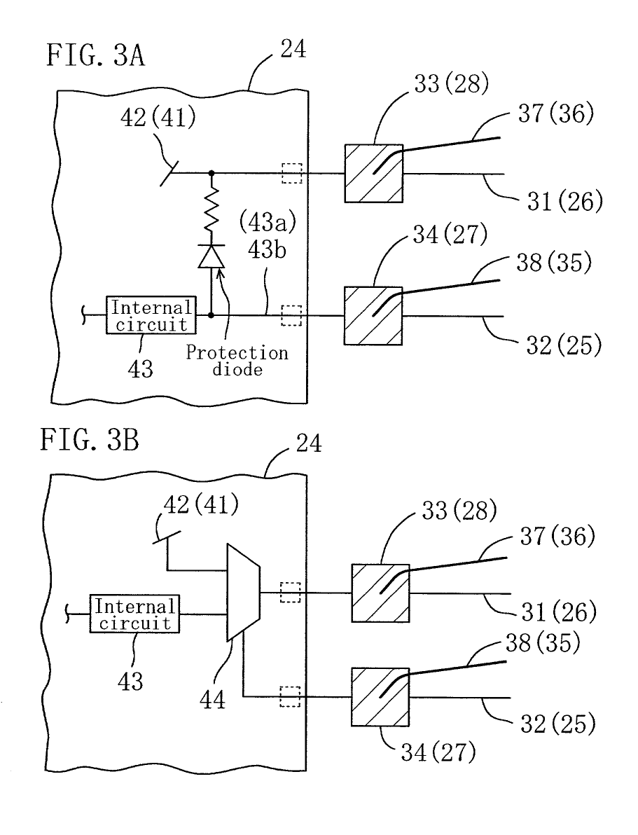

FIG. 3A is a block circuit diagram illustrating a first testing method for testing the connection between an IP (chip IP) and wiring. As illustrated in the figure, when testing the electrical connection between the wires 31 and 32 and the IP 24, a negative voltage is applied from a test pin 37 via the test pad 33 to the power supply line 42 in the IP 24. If the electrical connection is good, a forward current flows, according to a forward voltage, from a node 43b of the internal circuit 43 of the IP 24 to a protection diode (provided in an MOS transistor that is typically connected to an input/output pad). Therefore, by detecting a current or by detecting a voltage according to a voltage drop using a test pin 38, it is possible to determine the condition of the electrical connection between the IP and the wire in the silicon wiring substrate (for example, the condition of the connection between pads shown by broken lines in the figure) based on the measured voltage or current value.

When testing the electrical connection between the wires 25 and 26 and the IP 24, a positive voltage is applied from a test pin 36 via the test pad 28 to the ground line 41 in the IP 24. If the electrical connection is good, a forward current flows, by a forward voltage, from a node 43a of the internal circuit 43 of the IP 24 to a protection diode. Therefore, by detecting a current or by detecting a voltage according to a voltage drop using a test pin 35, it is possible to determine the condition of the electrical connection between the IP and the wire in the silicon wiring substrate (for example, the condition of the connection between pads shown by broken lines in the figure) based on the measured voltage or current value.

Alternatively, a signal of a “0, 1” pattern may be input to the power supply line 42 or the ground line 41.

FIG. 3B is a block circuit diagram illustrating a second testing method for testing the connection between an IP (chip IP) and wiring. As illustrated in the figure, a selector 44 is provided in the IP 24. The selector 44 receives, and selectively outputs one of, the output of the internal circuit 43 of the IP 24 and a power supply voltage VDD (ground voltage VSS), which is the output of the power supply line 42 (the ground line 41). When testing the electrical connection between the wires 31 and 32 and the IP 24, a logic voltage (e.g., H) such that the output of the power supply line 42 is selected is supplied to the selector 44 from the wire 32 via the test pad 34. Then, if the electrical connection is good, the power supply voltage VDD is output to the test pin 37 via the test pad 33. Therefore, the condition of the electrical connection can be determined by measuring the voltage of the test pin 37. When testing the electrical connection between the wires 25 and 26 and the IP 24, a logic voltage (e.g., H) such that the output of the ground line 41 is selected is supplied to the selector 44 from the test pin 35 via the test pad 27. Then, if the electrical connection is good, the ground voltage VSS is output to the test pin 36 via the test pad 28. Therefore, the condition of the electrical connection can be determined by measuring the voltage of the test pin 36.

In the test illustrated in FIG. 3B, a function test may be performed by inputting a test pattern to the test pin 38 (or 35).

In a conventional system LSI, or the like, test pads are provided along the periphery of a semiconductor device as a whole, which is to be the system LSI. However, in an IPOS device, the wiring pitch in the wiring layer of the silicon wiring substrate 20 is greater than that in a conventional system LSI, or the like, as described above. In view of this, the present invention employs a structure in which the test pads 27, 28, 33 and 34 are connected to certain points within the area of the wiring layer of the silicon wiring substrate 20. With such a structure, it is possible to easily and reliably determine the condition of the electrical connection between each IP (IP chip) mounted on the IPOS device and the wiring layer.

Second Embodiment

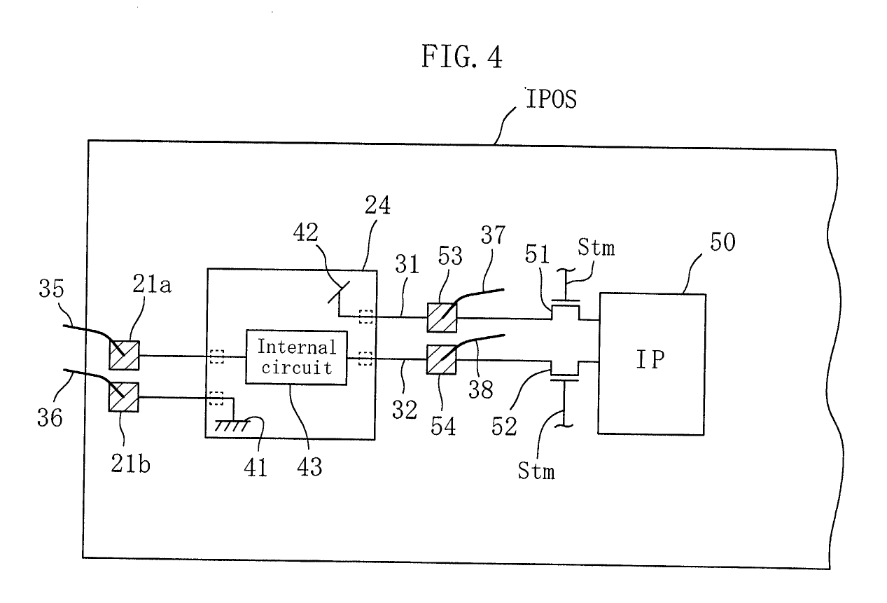

FIG. 4 is an enlarged plan view illustrating a portion of an IPOS device of the second embodiment. As illustrated in the figure, in the present embodiment, the IP 24 whose electrical connection is to be tested is connected directly to external terminal pads 21a and 21b, with the external terminal pad 21a being connected to the internal circuit 43 in the IP 24, and the external terminal pad 21b being connected to the ground line 41 (or the power supply line 42) of the IP 24. In this case, another IP 50 is provided adjacent to the IP 24 to be tested. Test pads 53 and 54 are provided connected to the wires 31 and 32, which connect the two IPs 24 and 50 to each other, and MOS transistors 51 and 52 are provided for turning OFF the electrical connection of the wires 31 and 32, respectively, according to the test mode signal Stm. Circuits in each IP are connected to the respective wires in the silicon wiring substrate via pads shown by broken lines in the figure (pads that are connected to the wiring on the silicon wiring substrate are shown overlapping with other pads that are connected to the circuits in the IP).

In the present embodiment, the electrical connection of the IP 24 can be tested as in the first embodiment by using the external terminal pads 21b and 21a, instead of the test pads 33 and 34 illustrated in FIG. 3A or FIG. 3B. Specifically, where the first testing method is used and the external terminal pad 21a is connected to the ground line 41, the condition of the electrical connection is determined by applying a positive voltage or a “0, 1” pattern signal to the ground line 41, and then measuring the output voltage or current. Where the external terminal pad 21a is connected to the power supply line 42, a negative voltage or a “0, 1” pattern signal is applied to the power supply line 42.

Where the second testing method is used and the external terminal pad 21a is connected to the ground line 41, a selector is provided for selectively outputting one of the voltage of the ground line 41 and the output of the internal circuit 43. The condition of the electrical connection is determined by applying the voltage VSS of the ground line 41 or a test pattern, and then measuring the output voltage or current. Where the external terminal pad 21a is connected to the power supply line 42, a negative voltage or a “0, 1” pattern signal is applied to the power supply line 42.

In the present embodiment, by using the external terminal pads 21a and 21b as test pads, the electrical connection between an IP (chip IP) connected to the external terminal pads and the silicon wiring substrate 20 can be tested, thus providing effects as those described above in the first embodiment.

Third Embodiment

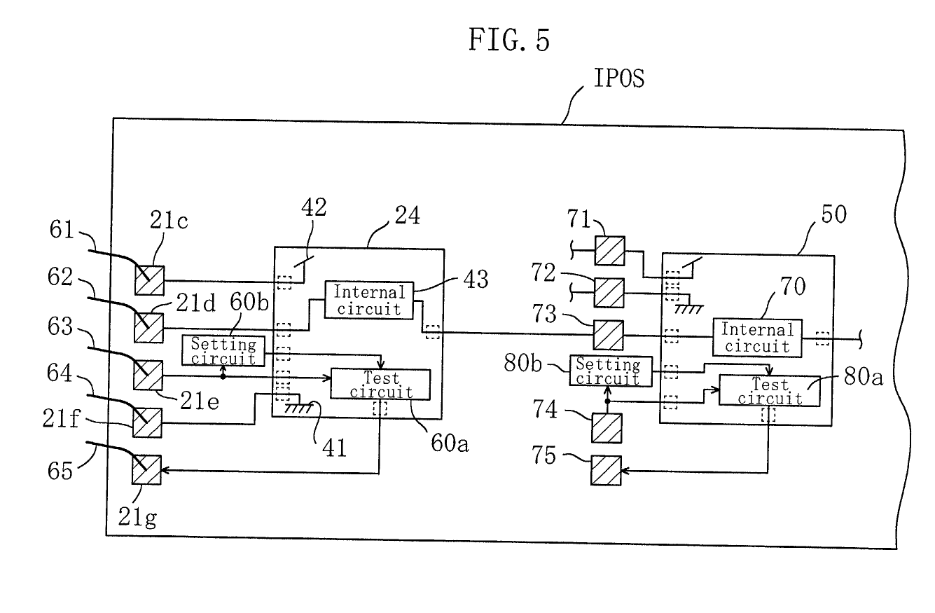

FIG. 5 is a is an enlarged plan view illustrating a portion of an IPOS device of the third embodiment. A feature of the present embodiment is that a test circuit 60a for generating a monitor signal is provided in the IP 24 whose electrical connection is to be tested, and a setting circuit 60b for setting a test mode is provided outside the IP 24.

In the present embodiment, external terminal pads 21c to 21g of the IPOS device are used as test pads. The external terminal pad 21c is connected to the power supply line 42 in the IP 24, the external terminal pad 21d to the internal circuit 43 in the IP 24, the external terminal pad 21e to the test circuit 60a and the setting circuit 60b, the external terminal pad 21f to the ground line 41 in the IP 24, and the external terminal pad 21g to the test circuit 60a. Circuits in each IP are connected to the respective wires in the silicon wiring substrate via pads shown by broken lines in the figure (pads that are connected to the wiring on the silicon wiring substrate are shown overlapping with other pads that are connected to the circuits in the IP).

When testing the electrical connection between the IP 24 and the silicon wiring substrate, test pins 61, 62, 63, 64 and 65 are contacted to the external terminal pads 21c, 21d, 21e, 21f and 21g, respectively. The power supply voltage and the ground voltage are supplied from the test pins 61 and 64 via the external terminal pads 21c and 21f, respectively.

Depending upon the structure of the test circuit 60a, an H-level or L-level signal is supplied as a test mode signal from the test pin 63 via the external terminal pad 21e to the internal circuit 43 in the IP 24. Then, all of the input/output terminals of the internal circuit 43 function only as input terminals, whereby the test can be performed irrespective of any signal from the internal circuit 43. Note, however, that it is not necessary to use the test pin 63 in a case where the input/output signals of the internal circuit 43 can all be brought to the H level or the L level by a signal from the setting circuit 60b. In such a case, there is a disadvantage that circuit scale of the setting circuit 60b increases. Therefore, either method should be selected depending upon the structure of the internal circuit in the chip IP.

An H-level or L-level signal is supplied as a test mode setting signal to the setting circuit 60b and the test circuit 60a from the test pin 63 via the external terminal pad 21e depending upon the structure of the test circuit 60a (e.g., whether the test circuit 60a is of a pull-down type or a pull-up type). Then, the monitor signal generated in the test circuit 60a is detected by the test pin 65 via the external terminal pad 21g.

Where the test circuit 60a has a pull-down type structure and an H-level signal is supplied to the internal circuit 43, the setting circuit 60b and the test circuit 60a, an H-level monitor signal is generated in the test circuit 60a if the IP 24 and the wiring layer of the silicon wiring substrate are properly connected to each other. If there is a disconnection, however, an L-level monitor signal is generated from the test circuit 60a because the voltage of the wire is pulled down. Thus, it is possible to determine the condition of the electrical connection based on the monitor signal.

Where the test circuit 60a has a pull-up type structure and an L-level signal is supplied to the internal circuit 43, the setting circuit 60b and the test circuit 60a, an L-level monitor signal is generated in the test circuit 60a if the IP 24 and the wiring layer of the silicon wiring substrate are properly connected to each other. If there is a disconnection, however, an H-level monitor signal is generated from the test circuit 60a because the voltage of the wire is pulled up. Thus, it is possible to determine the condition of the electrical connection between the IP 24 and the wiring layer of the silicon wiring substrate based on whether the monitor signal is an H-level signal or an L-level signal. Therefore, it is possible to test the electrical connection between each IP and the wiring of the silicon wiring substrate without performing a control using a clock signal.

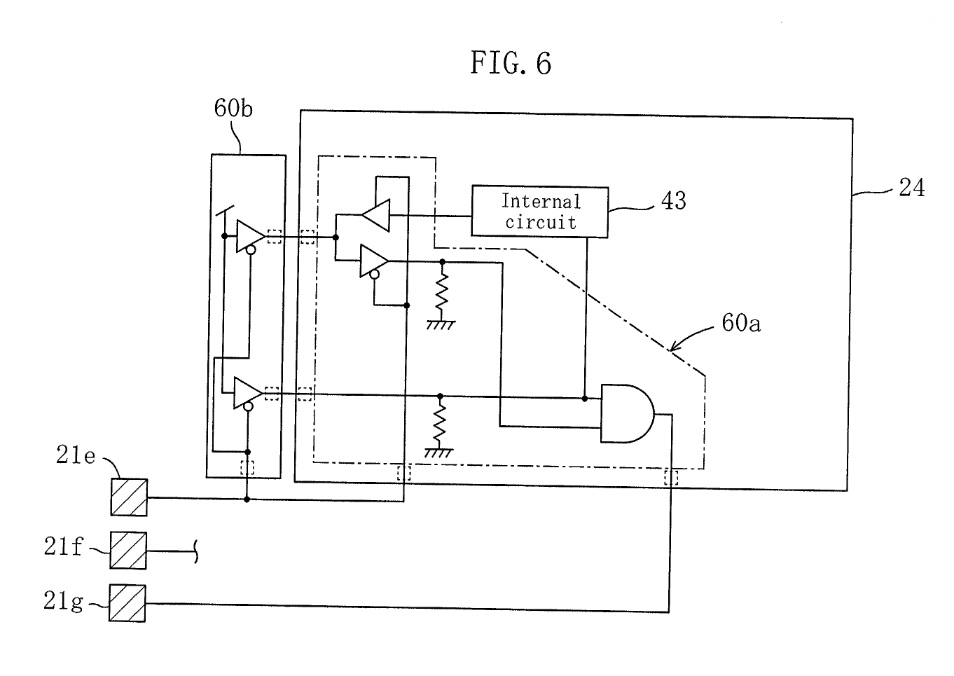

FIG. 6 is an electric circuit diagram of an IP and a setting circuit, illustrating an example where the test circuit 60a is of a pull-down type. Also in this figure, circuits in each IP are connected to the respective wires in the silicon wiring substrate via pads shown by broken lines in the figure (pads that are connected to the wiring on the silicon wiring substrate are shown overlapping with other pads that are connected to the circuits in the IP). With such a structure, an H-level monitor signal is output from an AND circuit in the last stage in the test circuit 60a if all the electrical connection is properly established. However, if an H-level signal is not supplied from a wire due to a disconnection, the voltage at an internal node is pulled down, whereby an L-level monitor signal is output from the AND circuit in the last stage. Thus, it can be seen that it is possible to determine the condition of the electrical connection between the IP 24 and the wiring layer of the silicon wiring substrate based on whether the monitor signal is an H-level signal or an L-level signal. Similarly, where the test circuit is of a pull-up type, it is possible to determine that the electrical connection is good if the monitor signal is an L-level signal and that the electrical connection is no good if the monitor signal is an H-level signal.

After completion of the electrical connection test, it is ensured that a signal of the opposite level to the test mode signal is supplied to the test circuit 60a by, for example, connecting the pad that gives the test mode signal (in this example, the external terminal pad 21e) to the ground line (or the power supply line). In this way, the test circuit is prevented from operating during an actual use of the IP 24 (chip IP), thereby avoiding a problem during an actual use of the IPOS device.

It is possible to provide and use, instead of the external terminal pads, test pads 71 to 75 that are connected to certain points within the area of the wiring layer of the silicon wiring substrate, as illustrated in FIG. 5. In such a case, a test circuit 80a may be provided in the IP 50, and a setting circuit 80b for outputting a test mode signal may be provided outside the IP 50. Also in such a case, it is possible to test the condition of the electrical connection between the IP 50 and the wiring layer (or pads) of the silicon wiring substrate by using the circuit illustrated in FIG. 6, for example.

Note, however, that the use of external terminal pads provides a significant effect that the condition of the electrical connection can be determined after packaging the chip IP (IP) mounted on the silicon wiring substrate. Since a pad that is connected to the power supply line and a pad that is connected to the ground line are connected to the various chip IPs, the number of such pads will not increase even if the number of chip IPs increases. The external terminal pad connected to the setting circuit can also be used commonly among various chip IPs. Therefore, it is only necessary to provide the external terminal pad connected to the test circuit for each IP, so that it is possible to test the electrical connection after packaging the all chip IPs of the IPOS device.

Alternatively, the setting circuit for inputting a test mode signal may also be incorporated in each IP.

Fourth Embodiment

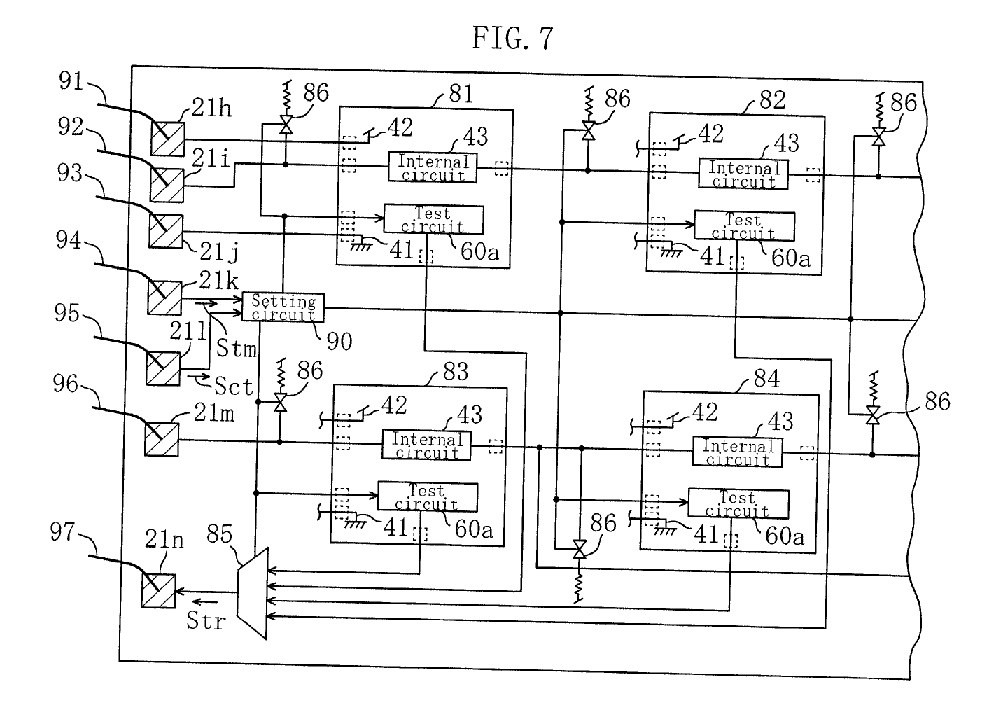

FIG. 7 is an enlarged plan view illustrating a portion of an IPOS device of the fourth embodiment. A feature of the present embodiment is that the test circuit 60a for generating a monitor signal is provided in each of IPs 81, 82, 83, 84, . . . , whose electrical connection is to be tested, while a setting circuit 90 for setting a test mode, a selector 85 for receiving the output of the setting circuit 90 at its control port and the output of each test circuit 60a at its input port, and a wiring disconnection switch 86 for turning ON/OFF the electric conduction between the wiring on the silicon wiring substrate and the power supply, are provided on the silicon wiring substrate outside the IPs. Circuits in each IP are connected to the respective wires in the silicon wiring substrate via pads shown by broken lines in the figure (pads that are connected to the wiring on the silicon wiring substrate are shown overlapping with other pads that are connected to the circuits in the IP).

In the present embodiment, external terminal pads 21h to 21n of the IPOS device are used as test pads. The external terminal pad 21h is connected to the power supply line 42 in each of the IPs 81, 82, 83, 84, . . . , the external terminal pads 21i and 21m to the internal circuits 43 in the IPs 81, 82, 83, 84, . . . via the wiring disconnection switches 86, the external terminal pad 21j to the ground line 41 in each of the IPs 81, 82, 83, 84, . . . , the external terminal pads 21k and 211 to the setting circuit 90, and the external terminal pad 21n to the output side of the selector 85 for selectively outputting one of the respective outputs of the test circuits 60a in the IPs 81, 82, 83, 84 . . . . Each wire of the silicon wiring substrate is connected to the power supply via a resistor and is pulled up.

When testing the electrical connection between the IPs 81, 82, 83, 84, . . . , and the silicon wiring substrate, test pins 91, 92, 93, 94, 95, 96 and 97 are contacted to the external terminal pads 21h, 21i, 21j, 21k, 21l, 21m and 21n, respectively. The power supply voltage and the ground voltage are supplied from the test pins 91 and 93 via the external terminal pads 21h and 21j, respectively.

An H-level signal or an L-level signal is supplied as a test mode signal to the internal circuit 43 of one of the IPs 81, 82, 83, 84, . . . , from the test pin 92 or 96 via the external terminal pad 21i or 21m, depending upon whether the test circuit 60a is of a pull-down type or a pull-up type. Then, all of the input/output terminals of the internal circuit 43 function only as input terminals, whereby the test can be performed irrespective of any signal from the internal circuit 43. The connection condition between the IPs 81, 82, 83, 84, . . . , and the wiring layer (or pads) of the silicon wiring substrate can be tested successively on an IP-by-IP basis by supplying, to the setting circuit 90, the test mode signal Stm from the test pin 94 and a cyclic control signal Sct from the test pin 95, and turning ON/OFF each wiring disconnection switch 86 and switching the selector 85 through the setting circuit 90.

With this method, it is possible to test the condition of the connection between all the IPs 81, 82, 83, 84, . . . , and the wiring layer (or pads) of the silicon wiring substrate.

According to the present invention, a semiconductor device and a testing method therefor are obtained with which it is possible to ensure the reliability of the connection between the semiconductor wiring substrate and the chip IPs mounted thereon.

What is claimed is:

1. A semiconductor device, comprising:
a semiconductor wiring substrate including a plurality of wires;
a chip IP including a circuit having semiconductor device elements arranged therein, the chip IP being attached to and mounted on the semiconductor wiring substrate so that the circuit is electrically connected to the plurality of wires of the semiconductor wiring substrate; and
at least one test pad connected to at least one of the wires of the semiconductor wiring substrate for testing an electrical connection between the circuit of the chip IP and the wires.

2. The semiconductor device of claim 1, wherein the test pad is an external terminal pad of the semiconductor device.

3. The semiconductor device of claim 1, wherein the test pad is a portion of the at least one of the wires that is exposed on a surface of the semiconductor wiring substrate.

4. The semiconductor device of claim 1, wherein:
the circuit of the chip IP includes a power supply line for supplying a power supply voltage and a node forming a protection diode between the power supply line and the node; and
the test pad includes a first test pad connected to a wire that is connected to the power supply line and a second test pad connected to a wire that is connected to the node in the circuit.

5. The semiconductor device of claim 1, wherein:
the circuit of the chip IP includes a ground line for supplying a ground voltage and a node forming a protection diode between the ground line and the node; and
the test pad includes a first test pad connected to a wire that is connected to the ground line and a second test pad connected to a wire that is connected to the node in the circuit.

6. The semiconductor device of claim 1, wherein:
the circuit of the chip IP includes a ground line for supplying a ground voltage, a power supply line for supplying a power supply voltage, and a selector for receiving, and selectively outputting one of, a signal of the ground line or the power supply line and an output signal of an output section of the circuit; and
the test pad includes a first test pad connected to a wire for supplying a switching control signal for the selector and a second test pad connected to an output section of the selector.

7. The semiconductor device of claim 1, wherein a switching element for turning ON/OFF transmission of a signal from the test pad is provided at a position that is along each of the plurality of wires of the semiconductor wiring substrate connected to the test pad and opposite to the chip IP with respect to the test pad.

8. The semiconductor device of claim 1, further comprising:
a test circuit provided in the chip IP for testing an electrical connection between the circuit of the chip IP and the wires; and
a setting circuit for setting at least the test circuit in a test mode,
wherein the test pad includes a first test pad for supplying a test mode signal to the test circuit and the setting circuit and a second test pad for receiving an output of the test circuit.

9. The semiconductor device of claim 8, wherein the test circuit has a pull-down type circuit structure or a pull-up type circuit structure.

10. The semiconductor device of claim 8, wherein the setting circuit is provided in the chip IP.

11. The semiconductor device of claim 8, wherein the setting circuit is provided in a chip different from the chip IP.

12. The semiconductor device of claim 8, wherein:
the circuit of the chip IP includes a power supply line for supplying a power supply voltage and a ground line for supplying a ground voltage; and
the semiconductor device further comprises:
a third pad connected to a wire that is connected to the power supply line; and
a fourth pad connected to a wire that is connected to the ground line.

13. A method for testing a semiconductor device, the semiconductor device including: a semiconductor wiring substrate including a plurality of wires; and a chip IP including an internal circuit, the internal circuit including a power supply line for supplying a power supply voltage and a node forming a protection diode between the power supply line and the node, the chip IP being attached to and mounted on the semiconductor wiring substrate so that the internal circuit is electrically connected to the plurality of wires of the semiconductor wiring substrate,
the method comprising, after forming a first test pad connected to one of the plurality of wires that is connected to the power supply line and a second test pad connected to another one of the plurality of wires that is connected to the node in the circuit, the steps of:
(a) supplying a voltage lower than a voltage of the power supply line via the first test pad to the power supply line; and
(b) detecting a voltage or a current at the node of the circuit via the second test pad, thereby testing an electrical connection between the circuit of the chip IP and the plurality of wires.

14. A method for testing a semiconductor device, the semiconductor device including: a semiconductor wiring substrate including a plurality of wires; and a chip IP including an internal circuit, the internal circuit including a ground line for supplying a ground voltage and a node forming a protection diode between the ground line and the node, the chip IP being attached to and mounted on the semiconductor wiring substrate so that the internal circuit is electrically connected to the plurality of wires of the semiconductor wiring substrate,
the method comprising, after forming a first test pad connected to one of the plurality of wires that is connected to the ground line and a second test pad connected to another one of the plurality of wires that is connected to the node in the circuit, the steps of:
(a) supplying a voltage higher than a voltage of the ground line via the first test pad to the ground line; and
(b) detecting a voltage or a current at the node of the circuit via the second test pad, thereby testing an electrical connection between the circuit of the chip IP and the plurality of wires.

15. A method for testing a semiconductor device, the semiconductor device including: a semiconductor wiring substrate including a plurality of wires; and a chip IP including an internal circuit, the internal circuit including a power supply line for supplying a power supply voltage and a node forming a protection diode between the power supply line and the node, the chip IP being attached to and mounted on the semiconductor wiring substrate so that the internal circuit is electrically connected to the plurality of wires of the semiconductor wiring substrate,
the method comprising, after forming a test circuit in the chip IP for testing an electrical connection between the circuit of the chip IP and the wires and a setting circuit for setting the circuit in the chip IP and the test circuit in a test mode,
and after forming a first test pad connected to one of the plurality of wires that is connected to the setting circuit and a second test pad connected to another one of the plurality of wires that is connected to the test circuit, the steps of:
(a) inputting a test mode setting signal via the first test pad to the setting circuit and the test circuit; and
(b) detecting an output of the test circuit via the second test pad, thereby testing the electrical connection between the circuit of the chip IP and the plurality of wires.

16. The method for testing a semiconductor device of claim 15, wherein:
the test circuit is formed to have a pull-down type circuit structure;
in the step (a), the test mode setting signal is input so that an H-level signal is output from the setting circuit; and
in the step (b), the electrical connection between the chip IP and the plurality of wires is determined to be good when the output from the test circuit is at an H level.

17. The method for testing a semiconductor device of claim 15, wherein:
the test circuit is formed to have a pull-up type circuit structure;
in the step (a), the test mode setting signal is input so that an L-level signal is output from the setting circuit; and
in the step (b), the electrical connection between the chip IP and the plurality of wires is determined to be good when the output from the test circuit is at an L level.

18. The method for testing a semiconductor device of claim 15, wherein:
a plurality of the chip IPs are provided;
the circuit of each chip IP includes a power supply line for supplying a power supply voltage and a ground line for supplying a ground voltage;
the semiconductor device further comprises:
a third pad connected to a wire that is connected to the power supply line;
a fourth pad connected to a wire that is connected to the ground line;
a switching device for turning ON/OFF an electric conduction of a wire between the chip IPs; and
a selector for switching outputs from the respective chip IPs from one to another,
wherein the switching device and the selector are controlled by the setting circuit so that the steps (a) and (b) are performed successively for each of the chip IPs.
